(19) United States
(12) Patent Application Publication
(10) Pub. No.: US 2013/0015309 A1
(43) Pub. Date: Jan. 17, 2013

(54) MOUNTING APPARATUS FOR STORAGE DEVICE

(71) Applicant: CHEN-LU FAN, Tu-Cheng (TW)

(72) Inventor: CHEN-LU FAN, Tu-Cheng (TW)

(73) Assignee: HON HAI PRECISION INDUSTRY CO., LTD., Tu-Cheng (TW)

(21) Appl. No.: 13/411,915

(22) Filed: Mar. 5, 2012

(30) Foreign Application Priority Data
Jul. 15, 2011 (CN) 201110198798.1

(51) Int. Cl. H05K 7/14

(52) U.S. Cl. 248/309.1

(57) ABSTRACT

A mounting apparatus includes a bracket and a tray. The bracket is capable of securing a first storage device and includes a bottom plate and two side plates located on the bottom plate. The tray includes a top panel, a first side panel, a second side panel and a third side panel. The first side panel, the second side panel and the third side panel are located on the top panel. The first side panel is located between the first side panel and the second side panel. The tray is capable of securing a second storage device between the first side panel and the third side panel. The tray is secured to the bracket, each of the first side panel and the second side panel is secured to each of the two side plates of the bracket.

### BACKGROUND

1. Technical Field

The present disclosure relates to mounting apparatuses, and more particularly to a mounting apparatus with a bracket.

2. Description of Related Art

Disk drives are usually provided in a computer system. The disk drives are secured to a bracket of a computer case. Conventionally, the bracket is shaped for receiving a same type of the disk drives, which have same sizes. Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a mounting apparatus and a storage device in accordance with an embodiment.

FIG. 2 is similar to FIG. 1, but viewed in a different aspect.

FIG. 3 is similar to FIG. 2, but shows the storage device secured in a tray of FIG. 2.

FIG. 4 is an isometric view of assembly of the mounting apparatus and the storage device of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

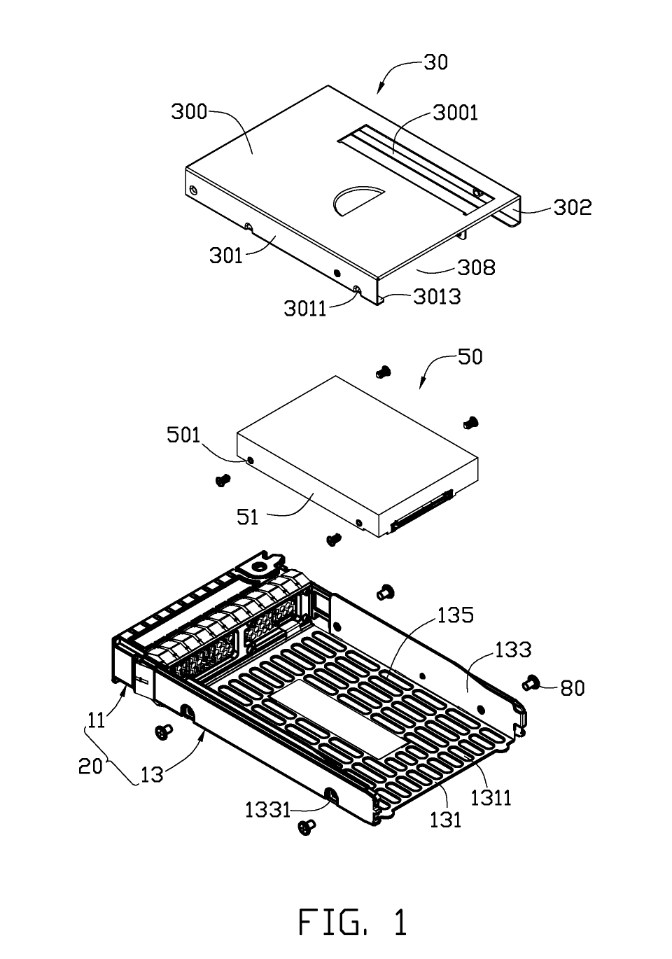

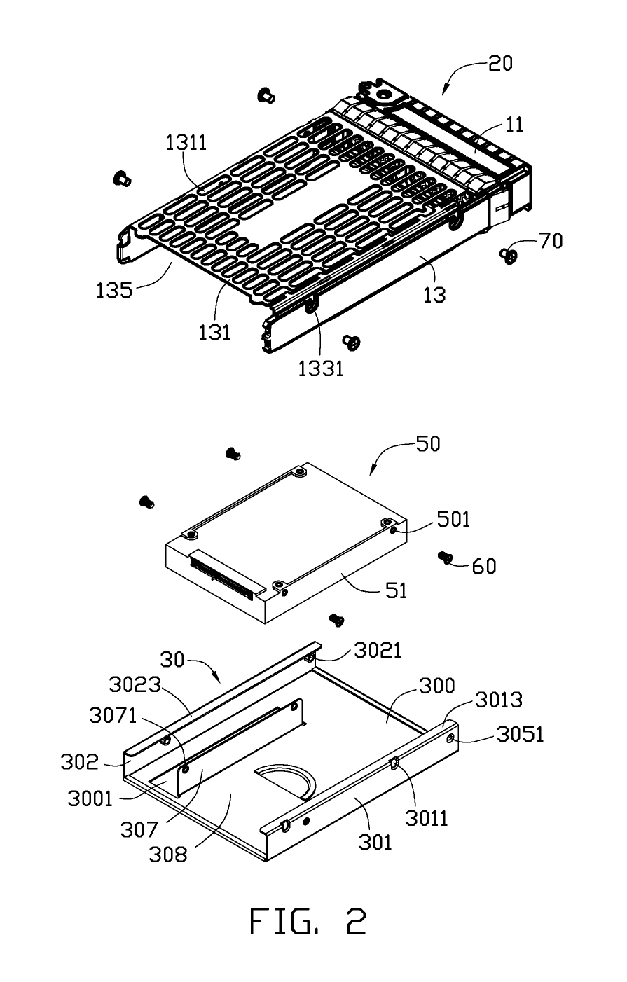

Referring to FIGS. 1-2, a mounting apparatus is configured for securing a first storage device (not shown) and a second storage device 50. The second storage device 50 is smaller than the first storage device. In an embodiment, the first storage device and the second storage device 50 may be hard disk drives, floppy disk drives, compact disc read-only memory disk drives, and so on. The second storage device 50 includes two opposite sidewalls 51, and each sidewall 51 defines two mounting holes 501.

The mounting apparatus in accordance with an embodiment includes a bracket 20 and a tray 30.

The bracket 20 includes a locking portion 11 and a body 13. The locking portion 11 is secured to the body 13 and capable of securing the bracket 20 to a case, such as a computer case. The body 13 includes a bottom plate 131 and two opposite side plates 133 located on opposite edges of the bottom plate 131. The bottom plate 131 and the two side plates 133 cooperatively define a holding space 135, which is capable of securing the first storage device. In one embodiment, the two side plates 133 are substantially parallel to each other and perpendicular to the bottom plate 131. The bottom plate 131 defines a plurality of ventilation holes 1311. Each side plate 133 defines two through holes 1331.

The tray 30 includes a top panel 300, a first side panel 301 and a second side panel 302. The first side panel 301 and the second side panel 302 are located on opposite edges of the top panel 300. The top panel 300, the first side panel 301 and the second side panel 302 corporately defines a receiving space 308, which is capable of securing a second storage device 50. The top panel 300 defines a through opening 3001. A third side panel 307 extends from an edge of the through opening 3001. The third side panel 307 is located between the first side panel 301 and the second side panel 302. In one embodiment, the first side panel 301, the second side panel 302 and the third side panel 307 are substantially parallel to each other and perpendicular to the top panel 300. The first side panel 301 defines two first locking holes 3011 and two fourth locking holes 3051, the second side panel 302 defines two second locking holes 3021, and the third side panel 307 defines two third locking holes 3071. A first flange 3013 extends from a bottom edge of the first side panel 301, and a second flange 3023 extends from a bottom edge of the second side panel 302. In an embodiment, the first flange 3013 is substantially perpendicular to the first side panel 301, and the second flange 3023 is substantially perpendicular to the second side panel 302.

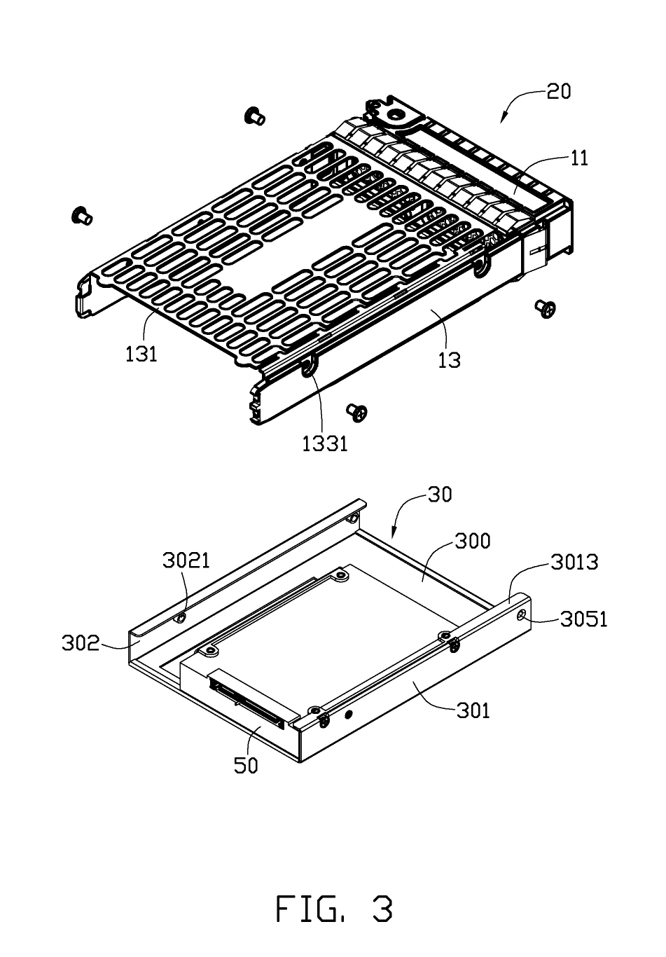

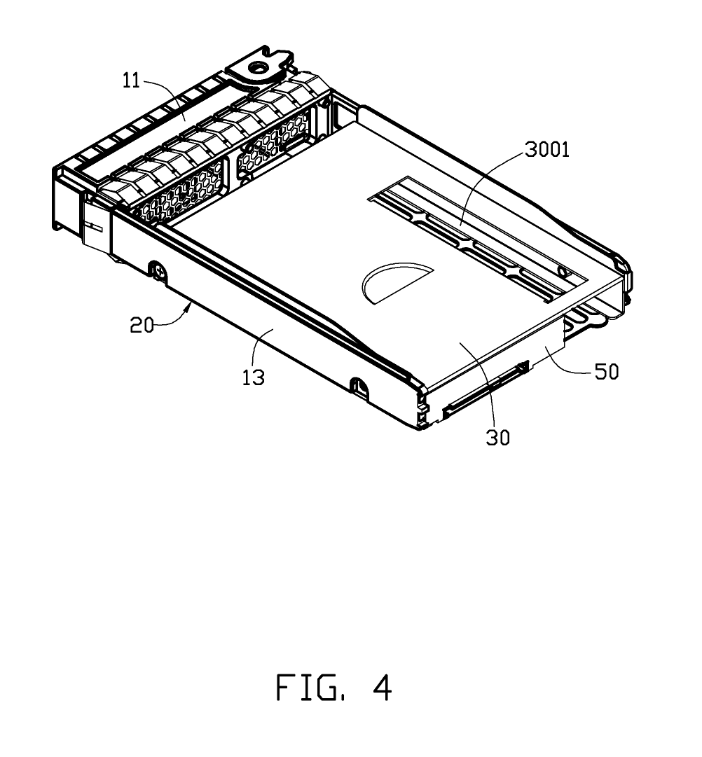

Referring to FIGS. 3 and 4, the second storage device 50 is placed in the tray 30 between the first side panel 301 and the third side panel 307. The mounting holes 501 of the second storage device 50 are aligned with the two first locking holes 3011 and the third locking holes 3071. Four first fasteners 60, such as screws, are inserted through the two first locking holes 3011 and the third locking holes 3071, and the first fasteners 60 are fixed in the corresponding mounting holes 501. Therefore, the second storage device 50 is secured to the tray 30.

The assembly of the tray 30 and the second storage device 50 is placed in the bracket 20 between the two side plates 133. The first flange 3013 and the second flange 3023 of the tray 30 abut the bottom plate 131 of the bracket 10. The two fourth locking holes 3051 of the first side panel 301 and the two second locking holes 3021 of the second side panel 302 are aligned with the four through holes 1331 of the two side plates 133. Four second fasteners 80, such as screws, are inserted through the four through holes 1331 and fixed into the two fourth locking holes 3051 and the two second locking holes 3021. Therefore, the assembly of the tray 30 and the second storage device 50 is secured in the bracket 10.

The bracket 10 can be also to secure the first storage device. Before the first storage device is installed in the bracket 10, the assembly of the tray 30 and the second storage device 50 should be removed from the bracket 10. When assembling the first storage device, the first storage device is placed in the bracket 10 and secured in the bracket with screws.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A mounting apparatus comprising:
a bracket comprising a bottom plate and two side plates located on the bottom plate, the bracket capable of securing a first storage device between the two side plates; and
a tray comprising a top panel, a first side panel, a second side panel and a third side panel; the first side panel, the second side panel and the third side panel located on the top panel; the first side panel located between the first side panel and the second side panel; and the tray capable of securing a second storage device between the first side panel and the third side panel;
wherein the tray is secured to the bracket, each of the first side panel and the second side panel are secured to each of the two side plates of the bracket.

2. The mounting apparatus of claim 1, wherein the two side plates of the bracket are substantially perpendicular to the bottom plate; and the first side panel, the second side panel and the third side panel are substantially perpendicular to the top panel.

3. The mounting apparatus of claim 1, wherein the two side plates of the bracket are substantially parallel to each other, and the first side panel of the tray is substantially parallel to the second side panel and the two side plates.

4. The mounting apparatus of claim 3, wherein the third side panel of the tray is substantially parallel to the first side panel and the second side panel.

5. The mounting apparatus of claim 1, wherein the top panel of the tray defines a through opening between the first side panel and the second side panel, and the third side panel extends from an edge of the through opening.

6. The mounting apparatus of claim 5, wherein the through opening is located between the second side panel and the third side panel.

7. The mounting apparatus of claim 1, wherein a first flange extends from the first side panel; a second flange extends from the second side panel; and the first flange and the second flanges abuts the bottom plate of the bracket.

8. The mounting apparatus of claim 7, wherein the first flange is substantially perpendicular to the first side panel, and the second flange is substantially perpendicular to the second side panel.

9. The mounting apparatus of claim 1, wherein two first locking holes are defined in the first side panel, two third locking holes are defined in the third side panel, the two first locking holes are aligned with the two third locking holes, and four first fasteners are capable of inserting through the two first locking holes and the two third locking holes to engage with the second storage device.

10. The mounting apparatus of claim 1, wherein two through holes are defined in each of the two side plates, two fourth locking holes are defined in the first side panel, two second locking holes are defined in the second side panel, and four second fasteners are capable of inserting through the two through holes of each of the two side plates to engage in the two fourth locking holes and the two second locking holes, to secure the tray to the bracket.

11. A mounting apparatus comprising:
a bracket comprising a bottom plate and two side plates located on the bottom plate, the bottom plate and the two side plates corporately define a holding space, which is capable of securing a first storage device; and
a tray comprising a top panel, a first side panel, a second side panel and a third side panel; the first side panel, the second side panel and the third side panel located on the top panel; the first side panel located between the first side panel and the second side panel; and the top panel, the first side panel and the third side panel corporately define a receiving space, which is capable of securing a second storage device;
wherein the tray is secured to the bracket, each of the first side panel and the second side panel are secured to each of the two side plates of the bracket.

12. The mounting apparatus of claim 11, wherein the two side plates of the bracket are substantially perpendicular to the bottom plate; and the first side panel, the second side panel and the third side panel are substantially perpendicular to the top panel.

13. The mounting apparatus of claim 11, wherein the two side plates of the bracket are substantially parallel to each other, and the first side panel of the tray is substantially parallel to the second side panel and the two side plates.

14. The mounting apparatus of claim 13, wherein the third side panel of the tray is substantially parallel to the first side panel and the second side panel.

15. The mounting apparatus of claim 11, wherein the top panel of the tray defines a through opening between the first side panel and the second side panel, and the third side panel extends from an edge of the through opening.

16. The mounting apparatus of claim 15, wherein the through opening is located between the second side panel and the third side panel.

17. The mounting apparatus of claim 11, wherein a first flange extends from the first side panel; a second flange extends from the second side panel; and the first flange and the second flanges abuts the bottom plate of the bracket.

18. The mounting apparatus of claim 17, wherein the first flange is substantially perpendicular to the first side panel, and the second flange is substantially perpendicular to the second side panel.

19. The mounting apparatus of claim 11, wherein two first locking holes are defined in the first side panel, two third locking holes are defined in the third side panel, the two first locking holes are aligned with the two third locking holes, and four first fasteners are capable of inserting through the two first locking holes and the two third locking holes to engage with the second storage device.

20. The mounting apparatus of claim 11, wherein two through holes are defined in each of the two side plates, two fourth locking holes are defined in the first side panel, two second locking holes are defined in the second side panel, and four second fasteners are capable of inserting through the two through holes of each of the two side plates to engage in the two fourth locking holes and the two second locking holes, to secure the tray to the bracket.
